(19) United States
(12) Patent Application Publication
(10) Pub. No.: US 2025/0226039 A1
(43) Pub. Date: Jul. 10, 2025

(54) SELECTIVE SLOW PROGRAMMING CONVERGENCE PROGRAM OPERATION WITH PROGRAM VERIFY LOOP DEPENDENT BITLINE VOLTAGE ADJUSTMENT

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 18/983,959

(22) Filed: Dec. 17, 2024

Related U.S. Application Data
(60) Provisional application No. 63/617,551, filed on Jan. 4, 2024.

(51) Int. Cl. G11C 16/34; G11C 16/04; G11C 16/10; G11C 16/24

(52) U.S. Cl. CPC G11C 16/3459; G11C 16/10; G11C 16/24; G11C 16/0483

(57) ABSTRACT

Processing logic in a memory sub-system receives a request to execute a programming operation to program cells of a memory device to a set of programming levels. The processing logic executes a first program verify loop associated with a programming level of the set of programming levels, where the first program verify loop comprises applying an initial bitline voltage to a subset of the cells having a threshold voltage in a range between a pre-program verify voltage and a program verify voltage. The processing logic executes a subsequent program verify loop associated with the programming level, wherein the subsequent program verify loop comprises applying an adjusted bitline voltage to the subset of the cells.

### CROSS-REFERENCE TO RELATED APPLICATION

This application claims the benefit of U.S. Provisional Application No. 63/617,551, titled “Selective Slow Programming Convergence Program Operation with Program Verify Loop Dependent Bitline Voltage Adjustment,” filed Jan. 4, 2024, which is hereby incorporated herein by reference in its entirety.

### TECHNICAL FIELD

Embodiments of the disclosure relate generally to memory sub-systems, and more specifically, relate to a selective slow programming convergence program operation including program verify loop dependent adjustment of a bitline voltage applied to a subset of selective slow programming convergence cells of a memory device.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with one or more embodiments of the present disclosure.

FIG. 1B is a block diagram of a memory device in communication with a memory sub-system controller of a memory sub-system, in accordance with one or more embodiments of the present disclosure.

FIG. 2 is an example process flow relating to a selective slow programming convergence program operation including a program verify loop dependent adjustment of a bitline voltage applied to a subset of cells of a memory device of a memory sub-system, in accordance with one or more embodiments of the present disclosure.

FIG. 3 illustrates a diagram of example program verify loop dependent bitline voltage levels applied to a subset of cells having a threshold voltage in the range between a pre-program verify voltage and a program verify voltage during program verify loops for each programming level during a program operation of a memory device, in accordance with one or more embodiments of the present disclosure.

FIGS. 4A-4D illustrate an example of a selective slow programming convergence program operation to program a set of cells to a programming level including program verify loop dependent adjustment of a bitline voltage applied to a subset of selective slow programming convergence cells, according to embodiments of the present disclosure.

FIG. 5 is a flow diagram of an example method of a selective slow programming convergence program operation including program verify loop dependent adjustment of a bitline voltage applied to a subset of selective slow programming convergence cells, in accordance with one or more embodiments of the present disclosure.

FIG. 6 is a block diagram of an example computer system in which embodiments of the present disclosure may operate.

### DETAILED DESCRIPTION

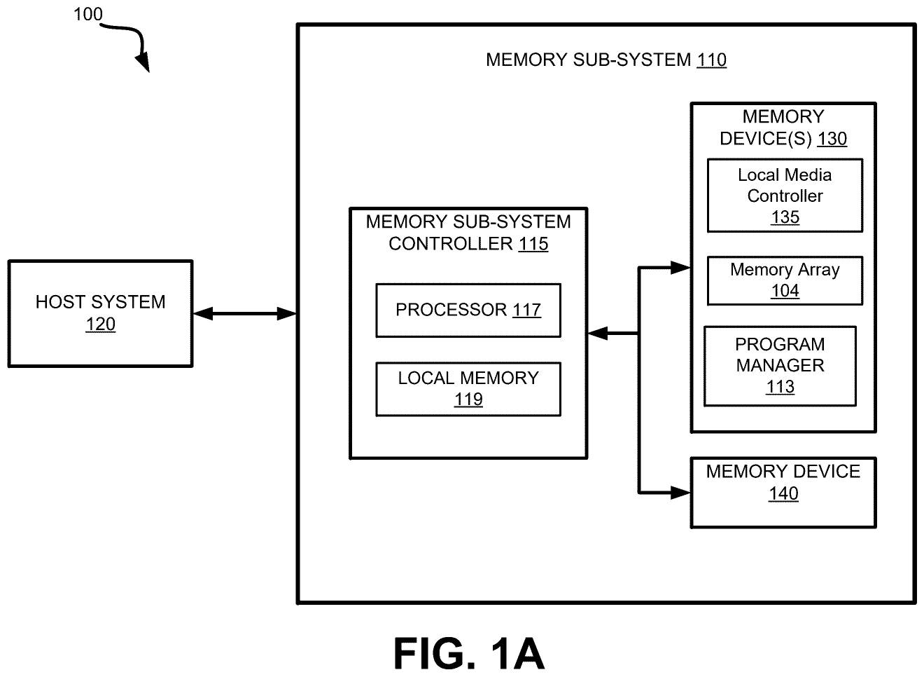

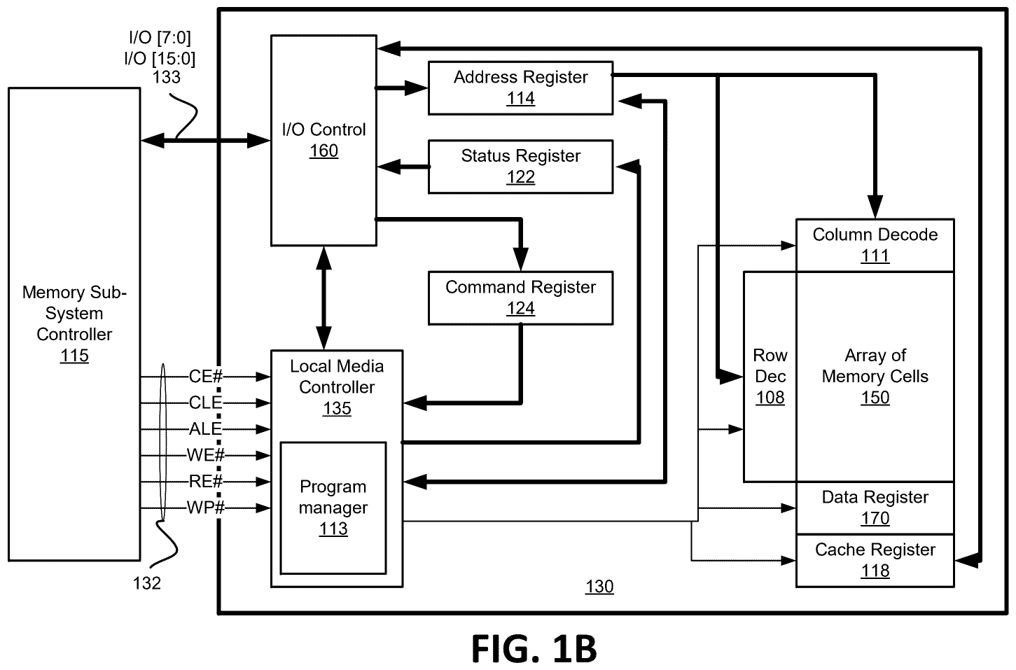

Aspects of the present disclosure are directed to a selective slow programming convergence program operation including program verify loop dependent adjustment of a bitline voltage applied to a subset of selective slow programming convergence cells of a memory device in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more memory dies, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

One type of cell is a single level cell (SLC), which stores 1 bit per cell and defines 2 logical states (“states”) (“1” or “L0” and “0” or “L1”) each corresponding to a respective VT level. For example, the “1” state can be an erased state and the “0” state can be a programmed state (L1). Another type of cell is a multi-level cell (MLC), which stores 2 bits per cell (1 bit for upper page (UP) data and 1 bit for lower page (LP) data) and defines 4 states (“11” or “L0”, “10” or “L1”, “01” or “L2” and “00” or “L3”) each corresponding to a respective VT level. For example, the “11” state can be an erased state and the “01”, “10” and “00” states can each be a respective programmed state. Another type of cell is a triple level cell (TLC), which stores 3 bits per cell (1bit for UP data, 1 bit for LP data and 1 bit for extra page (XP) data) and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell (1 bit for UP data, 1 bit for LP data, 1 bit for XP data, and 1 bit for top page (TP) data) and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2″ levels of charge to store n bits of information for n pages. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

To program data to a memory sub-system, an internal controller of the NAND can issue control signals to one or more row drivers to cause the row drivers to apply a voltage across the gates of a NAND device to trap charges (e.g., electrons) in a charge trap region of the NAND. The memory controller can apply the voltage in a pulse, known as a program pulse. The amount of voltage and the width of the pulse can determine the amount of charge that will be stored at the NAND device, and in turn programs the state of the NAND.

During a series of programming loops, the memory controller can apply a program pulse having a program voltage (VPGM) and, for each programming level, perform a set of program verify loops to verify the state of the NAND to bring the target cells to the intended voltage level associated with a target programming level. Accordingly, this program verify (PV) operation is performed during programming to determine whether memory cells are being programmed to their target memory states. This pulse-verify-pulse sequence can ensure that the memory device correctly programmed without applying a larger voltage that can cause more damage to the memory device.

However, in certain memory systems, charge loss occurs within memory cells in which a threshold voltage (Vt) of a memory cell can shift away from an originally-programmed level, making it more difficult to determine a logical state of the memory cell. Quick charge loss (QCL) is the quantity of charge loss, measurable in threshold voltage, that is lost from a memory cell soon after having been programmed, e.g., within a second or seconds. Some memory cells have more traps within polysilicon channel grain boundaries. These traps tend to either trap electrons or release electrons, depending on pre-programmed states of the traps. Memory cells that trap more electrons make cell Vt appear higher, leading to faster program speed, e.g., a lower program time (“tprog”). Memory cells that release more electrons make cell Vt appear lower, causing a slower program speed (e.g., a higher tprog). Thus, although two memory cells are programmed about the same time, the memory cells can experience different amounts of QCL. Further, cells with faster QCL exhibit larger shifts in threshold voltage distributions compared to cells with slower QCL. Ideally, QCL would be the same in all memory cells so that shifts in threshold voltage distributions are predictable, but the structural reality of trapping and releasing electrons, to the extent such is not preventable, has to be compensated for in some way. Additionally, due to technology scaling where cell volume size is being reduced, every additional electron trapped or released will have a larger impact to QCL in advanced memory devices.

In these memory systems, increase in charge loss (whether fast or slow charge loss) also tends to reduce read window budget (RWB) between adjacent threshold voltage distributions of logical states. As various RWBs are reduced, the memory device can exhibit higher bit error rates when reading out discrete logical states from the memory cells, e.g., it is more difficult to detect local minima between the adjacent threshold voltage distributions.

In this regard, faster cells are easier to program, but tend to have more QCL. Accordingly, faster cells have worse QCL, requiring a higher PV while slower cells have better QCL, requiring a lower PV. To address the differences in QCL between faster and slower cells, some systems dynamically adjust the PV voltage for each programming level. In this approach, a relatively higher PV voltage for a first or initial programming loop of a given programming level and a relatively lower PV voltage for subsequent programming loops of that programming level. However, due to QLC, the toggling of the PV voltage level during the PV loop results in wider programming distributions and a bit error rate associated with an undesirable RWB.

As a memory sub-system ages, the voltage (Vt) distributions of the NAND states of the memory cells tend to widen and therefore a higher program pulse can be required toward the end of the life of a memory sub-system to ensure data can properly be read. Therefore, the memory controller in conventional memory systems uses a program pulse that accounts for end of life conditions (i.e., begins with a larger program pulse voltage and/or width). However, using a larger program pulse at the beginning of the life of the memory sub-system can reduce the life span of the memory component because the larger program pulses can cause more damage to the NAND components unnecessarily, than if lower program pulses were used instead.

Certain memory access operations performed on a block of a memory device involve the application of certain voltages to the wordlines, as well as the pre-charging of the bitlines. In order to confirm whether a memory cell in the block is in an erase state “1” or program state “0,” a verification of a change in potential can be difficult to recognize unless the bitline is provided with a certain level of potential. Thus, certain devices apply a pre-charge voltage to increase the voltage of the bitline to a predetermined value in advance, followed by detecting a change in the voltage of the bitline when the bitline is applied to a memory cell by comparing the voltage of the bitline with the pre-charged voltage used as a reference. This pre-charging is performed frequently during memory access operations and, therefore, the time required for pre-charging has a large influence on data access time.

During certain memory access operations, one or more calculations are performed on the memory device prior to the pre-charging being initiated. One approach involves the use of selective slow program convergence (SSPC) to improve a program threshold voltage distribution width. In this approach, multiple pre-verify voltage levels (e.g., pre-program verify level (PPV) and a program verify level (PV)) are calculated prior to initiating the pre-charging. The SSPC approach involves slowing down the program speed when the cells enter the voltage region between pre-program verify (PPV) level and the PV level. During implementation of SSPC, the memory cells are programmed with incrementally increased programming pulses applied to wordlines to which the memory cells are coupled. After each pulse, a program verify operation determines the threshold voltage for each cell. When the threshold voltage reaches a pre-verify threshold, only the bitline connected to that particular cell is biased with a fixed or static intermediate voltage that slows down the change in the Vₜ of the cell. The other cells continue to be programmed at their normal pace. As the Vₜ for each cell reaches the pre-verify level, it is biased with the intermediate voltage. All of the bitlines are biased with an inhibit voltage as their threshold voltages reach the verify voltage threshold.

According to this approach, each bitline that is coupled to a memory cell of the plurality of memory cells is selectively biased with a first bitline voltage in response to the threshold voltage of the associated memory cell reaching a pre-verify threshold voltage. The pre-verify threshold voltage is less than a verify threshold voltage. The applied bitline voltage is a fixed digital voltage (e.g., a voltage in the range of 0.5V to 0.9V) that is typically greater than 0V and less than the inhibit voltage (e.g., V_{CC}). Since the WL potential increases among each program loop (also known as an incremental step program pulse (ISPP) approach), SSPC is achieved by raising the BL voltage to a fixed level (e.g., 0.5V to 0.8V), which reduces the electric field for F-N tunneling.

Another approach employed in certain systems is a dual SSPC method, which includes the implementation of an addition or second PPV level (e.g., PPV2) to the above-described SSPC method. In this approach, cells that enter a region between PPV2 and PPV have a different bitline bias voltage level compared to cells in the region between PPV and PV. However, this approach suffers from performance penalties, circuit complexity and additional data latch (chip area) costs.

Aspects of the present disclosure address the above and other deficiencies by implementing a programming operation with selective slow programming convergence (SSPC) processing with program verify (PV) loop dependent bitline voltage (Vbl) adjustment (herein the “adjusted bitline voltage SSPC program operation”) optimizing RWB gain. According to embodiments, the adjusted bitline voltage SSPC program operation identifies a set of cells having a threshold voltage (Vt) in a range between a pre-program verify (PPV) level and PV level (herein referred to as a “set of SSPC cells”). According to embodiments, the bitline voltage associated with the set of SSPC cells is adjusted based on the program verify loop (i.e., the adjusted bitline voltage levels are dependent on the number or count associated with the program verify loop).

In an embodiment, for an initial or first program verify loop of a set of program verify loops associated with programming loops for each programming level (e.g., programming level 1, programming level 2, etc.), a first bitline voltage level (VBL1) is applied to a set of SSPC cells (i.e., cells having a threshold voltage in a range between a PPV level and a PV level). The program verify loop count is monitored to determine when the program verify loop count satisfies a condition (i.e., reaches one of a set of predetermined values). According to embodiments, the condition is satisfied when the program verify loop count reaches a first count value (e.g., 1+N), a second count value (e.g., 1+2N), a third count value (e.g., 1+3N), etc., where N is an integer value (e.g., N=1, N=2, N=3, etc.). For example, when N=2, the condition is satisfied when the program verify loop count reaches the third program verify loop, the fifth program verify loop, etc. According to embodiments, for each program verify loop of each programming level, the program verify loop count is monitored and compared to the condition criteria to determine when the condition is satisfied. In response to satisfying the condition, an adjusted bitline voltage to be applied to the SSPC cells is established.

In an embodiment, in response to determining a current program verify loop count (i.e., a 1+Nth program verify loop) satisfies the condition, a first adjusted bitline voltage level (VBL_{1+N}) is established and applied to the SSPC cells, where VBL_{1+N} is greater than VBL₁. In an embodiment, VBL_{1+N} is set to a level equal to VBL₁ plus a step bitline voltage level (VBLₛₜₑₚ).

In an embodiment, in a second subsequent program verify loop (e.g., the 1+2N program verify loop), a second adjusted bitline voltage level (VBL_{1+2N}) is applied to the SSPC cells, where VBL_{1+2N} is greater than VBL_{1+N}. In an embodiment, VBL_{1+2N} is set to a level equal to VBL_{N} plus the step bitline voltage level (VBLₛₜₑₚ). In an embodiment, for each Y program verify loops, the bitline voltage can be increased by the step bitline voltage level (VBLₛₜₑₚ) until a final program verify loop is reached. In an embodiment, during the last or final program verify loop for each programming level, a final bitline voltage level (VBL_{final}) is applied to the SSPC cells. In an embodiment, the final bitline voltage level (VBL_{final}) can be equal to a change in the program voltage (ΔVPGM) divided by two (e.g., VBL_{final}=ΔVPGM/2). In an embodiment, the ΔVPGM represents the change or difference between the program voltages associated with the set of program pulses applied during the set of programming loops.

Advantageously, the SSPC with adjusted bitline voltage program operation causes the fast cells (i.e., the SSPC cells) to encounter more QCL and slow cells to encounter less QCL, which results in tighter threshold voltage distributions for the respective programming levels. Furthermore, the tighter threshold voltage distributions for each programming level results in improved RWB and better memory device reliability.

FIG. 1A illustrates an example computing system 100 that includes a memory sub-system 110 in accordance with some embodiments of the present disclosure. The memory sub-system 110 can include media, such as one or more ultra-high endurance storage class memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the PCIe interface. The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. For example, the ultra-high endurance storage class memory device 140 can include any of a number of different types of memory media or “cells” that are non-volatile and offer lower program/read latency than 3D NAND type flash memory, including both SLC memory and QLC memory. In addition, the ultra-high endurance storage class memory device 140 can have higher endurance (i.e., can tolerate a greater number of program/erase cycles) than memory device 130. Some examples of ultra-high endurance storage class memory include hybrid random access memory (HRAM), three-dimensional cross-point (“3D cross-point”) memory, or others.

Some examples of non-volatile memory devices (e.g., memory device(s) 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), or penta-level cells (PLCs) can store multiple bits per cell. In some embodiments, each of the memory devices 130 can include one or more arrays of memory cells such as SLCs, MLCs, TLCs, QLCs, PLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control or processing logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, the local controller 135 includes a program manager 113 that can implement a selective slow programming convergence (SSPC) program operation including application of a bitline voltage level to a set of cells that is adjusted based on a corresponding program verify loop during programming of a memory device in a memory sub-system. In an embodiment, the program manager 113 performs an initial program verify loop during the program operation. The program manager 113 identifies a subset of cells having a threshold voltage in a range between a pre-program verify (PPV) level and a program verify (PV) level. The subset of cells represents the fast programming cells that are subject to a higher level of QCL. During the initial or first program verify loop, an initial or first bitline voltage is applied to the identified subset of cells.

In an embodiment, the program manager 113 monitors the program verify loop count and increases the count upon completion of each program verify loop. According to embodiments, for each program verify loop of each programming level, the program verify loop count is monitored and compared to the condition criteria to determine when the condition is satisfied. In an embodiment, the condition is satisfied if the program verify loop count reaches one of a set of predetermined count values. According to embodiments, the condition is satisfied when the program verify loop count reaches a first count value (e.g., 1+N), a second count value (e.g., 1+2N), a third count value (e.g., 1+3N), etc., where N is an integer value (e.g., N=1, N=2, N=3, etc.). For example, when N=2, the condition is satisfied when the program verify loop count reaches the third program verify loop, the fifth program verify loop, etc.

In response to satisfying the condition, an adjusted bitline voltage to be applied to the SSPC cells is established. In an embodiment, the adjusted bitline voltage to be applied during a program verify loop having a count that satisfies the condition is established by adding a step bitline voltage level (VBLₛₜₑₚ) to a previously applied bitline voltage level. In an embodiment, an adjusted bitline voltage associated with a 1+N program verify loop is equal to the bitline voltage associated with program verify loop 1 plus the step bitline voltage level (VBLₛₜₑₚ).

According to embodiments, the program manager 113 adjusts the bitline voltage applied to subset of cells (i.e., the SSPC cells) in response to reaching the certain predetermined program verify loop counts (e.g., program verify loop 3, program verify loop 5, program verify loop 7, where N=2). In an embodiment, the adjusted bitline voltage for a program verify loop is set to a level equal to a current bitline voltage level plus a step bitline voltage level (VBLₛₜₑₚ).

In an embodiment, each time the condition is satisfied (i.e., the program verify loop count reaches a predetermined count value), the bitline voltage can be increased by the step bitline voltage level (VBLₛₜₑₚ), until a last or final program verify loop is reached. In an embodiment, during the last or final program verify loop for each programming level, a final bitline voltage level (VBL_{final}) is applied to the SSPC cells. In an embodiment, the final bitline voltage level (VBL_{final}) can be equal to a change in the program voltage (ΔVPGM) divided by two (e.g., VBL_{final}=ΔVPGM/2). In an embodiment, the ΔVPGM represents the change or difference between the program voltages associated with the set of program pulses applied during the set of programming loops.

Advantageously, the program manager 113 executes a SSPC program operation with adjusted bitline voltage to cause the identified fast cells (i.e., the SSPC cells having a threshold voltage in a range between a pre-program verify voltage (PPV) and a program verify voltage (PV)) to encounter more QCL and slow cells to encounter less QCL, which results in tighter threshold voltage distributions for the respective programming levels. Accordingly, the tighter threshold voltage distributions for each programming level result in improved RWB and better memory device reliability. Further details with regards to the operations of program manager 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 150 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 250 are capable of being programmed to one of at least two target data states.

Row decode circuitry 108 and column decode circuitry 111 are provided to decode address signals. Address signals are received and decoded to access the array of memory cells 150. Memory device 130 also includes input/output (I/O) control circuitry 112 to manage input of commands, addresses and data to the memory device 130 as well as output of data and status information from the memory device 130. An address register 114 is in communication with I/O control circuitry 160 and row decode circuitry 108 and column decode circuitry 111 to latch the address signals prior to decoding. A command register 124 is in communication with I/O control circuitry 112 and local media controller 135 to latch incoming commands.

A controller (e.g., the local media controller 135 internal to the memory device 130) controls access to the array of memory cells 150 in response to the commands and generates status information for the external memory sub-system controller 115, i.e., the local media controller 135 is configured to perform access operations (e.g., read operations, programming operations and/or erase operations) on the array of memory cells 150. The local media controller 135 is in communication with row decode circuitry 108 and column decode circuitry 110 to control the row decode circuitry 108 and column decode circuitry 110 in response to the addresses. In one embodiment, local media controller 135 includes program manager 113, which can implement the program verify loop dependent adjustment of the bitline voltage applied to identified SSPC cells during a program operation, as described herein.

The local media controller 135 is also in communication with a cache register 118. Cache register 118 latches data, either incoming or outgoing, as directed by the local media controller 135 to temporarily store data while the array of memory cells 150 is busy writing or reading, respectively, other data. During a program operation (e.g., write operation), data may be passed from the cache register 118 to the data register 121 for transfer to the array of memory cells 150; then new data may be latched in the cache register 118 from the I/O control circuitry 160. During a read operation, data may be passed from the cache register 118 to the I/O control circuitry 112 for output to the memory sub-system controller 115; then new data may be passed from the data register 121 to the cache register 118. The cache register 118 and/or the data register 121 may form (e.g., may form a portion of) a page buffer of the memory device 130. A page buffer may further include sensing devices (not shown in FIG. 1B) to sense a data state of a memory cell of the array of memory cells 150, e.g., by sensing a state of a data line connected to that memory cell. A status register 122 may be in communication with I/O control circuitry 112 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 133 and outputs data to the memory sub-system controller 115 over I/O bus 133.

For example, the commands may be received over input/output (I/O) pins [7:0] of I/O bus 133 at I/O control circuitry 112 and may then be written into command register 124. The addresses may be received over input/output (I/O) pins [7:0] of I/O bus 234 at I/O control circuitry 112 and may then be written into address register 114. The data may be received over input/output (I/O) pins [7:0] for an 8-bit device or input/output (I/O) pins [15:0] for a 16-bit device at I/O control circuitry 112 and then may be written into cache register 118. The data may be subsequently written into data register 121 for programming the array of memory cells 150.

In an embodiment, cache register 118 may be omitted, and the data may be written directly into data register 121. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

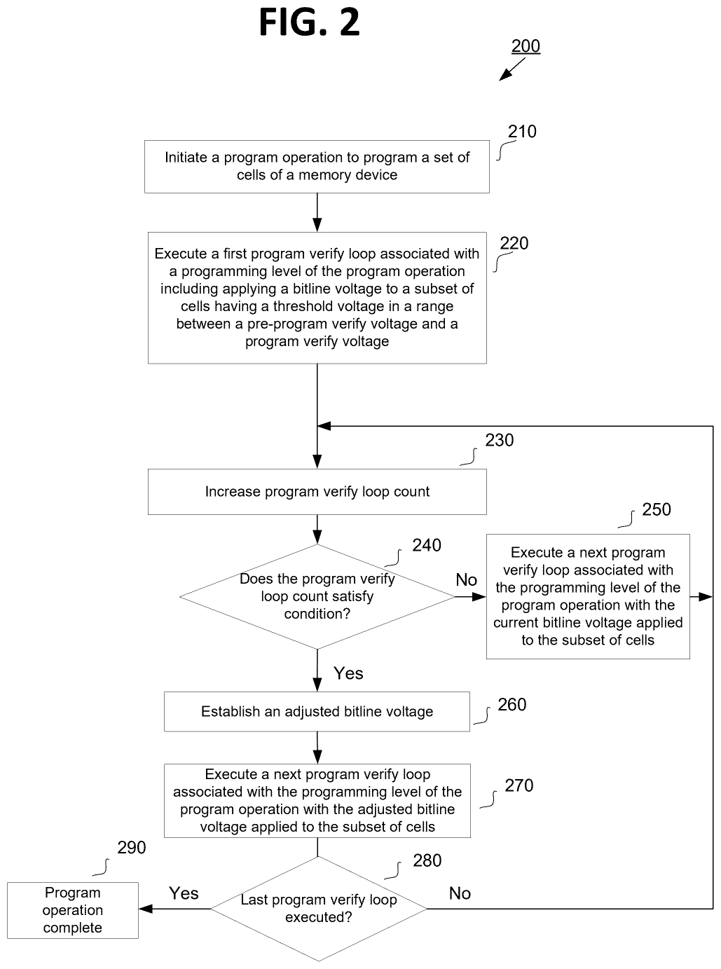

FIG. 2 is an example process flow 200 relating to a program verify loop dependent adjustment of bitline voltage applied to a subset of SSPC cells during a program operation associated with a memory device of a memory sub-system, according to embodiments of the present disclosure. As shown in FIG. 2, at block 210, control logic (e.g., program manager 113 of FIG. 1A and FIG. 1B) can cause initiation of a program operation to program a set of cells (i.e., a set of target cells) of a memory device. In an embodiment, the program operation is executed with selective slow programming convergence (SSPC) to identify a subset of the set of cells that have a threshold voltage in a range between a first voltage level (i.e., a pre-program verify voltage level (PPV)) and a second voltage level (i.e., a program verify voltage level (PV)).

At block 220, the control logic executes an initial or first program verify loop (PVFY loop 1) of a set of program verify loops corresponding to programming loops to program cells to a programming level (e.g., programming level 1, programming level 2, programming level 3 to programming level X) during a program operation. In an embodiment, the initial program verify loop (PVFY loop 1) includes applying an initial bitline voltage to a subset of cells having a threshold voltage in a range or region between a pre-program verify voltage (PPV) and a program verify voltage (PV) (i.e., a subset of SSPC or fast cells). In an example, the bitline voltage applied during the first program verify loop (e.g., VBL₁) is a default or initial value.

At block 230, following completion of the first program verify loop, the control logic increases a program verify loop count (e.g., the program verify loop count is increased from PVFY 1 to PVFY 2). At block 240, the control logic determines whether the program verify loop count value satisfy a condition. In an embodiment, the condition is satisfied if the program verify loop count value equals one of a set of predetermined program verify loop count values. In an embodiment, the condition can be satisfied if the program verify loop count value equals 1+N, 1+2N, 1+3N, etc., where N is an integer value. For example, if N=2, at block 230, the control logic determines if a current program verify loop count equals one of program verify loop 3 (i.e., 1+N), program verify loop 5 (1+2N), program verify loop 7 (1+3N), etc.

If the current program verify loop count does not satisfy the condition, the process 200 continues to block 250. In block 250, the control logic executes a next program verify loop associated with the programming level of the program operation with the current bitline voltage (i.e., the bitline voltage level applied during the previous program verify loop) applied to the subset of cells. Following block 250, the process 200 returns to block 230 and the program verify loop count is increased.

If the current program verify loop count satisfies the condition, the process 200 continues to block 260. In block 260, the control logic establishes an adjusted bitline voltage. In an embodiment, the adjusted bitline voltage equals the bitline voltage applied during the prior program verify loop increased by a step bitline voltage (VBLₛₜₑₚ). For example, where N=2, for program verify loop 3 (PVFY 3), the control logic establishes an adjusted bitline voltage (VBL_{1+N}or VBL₃) that is equal to the previous bitline voltage (VBL₁) plus the step bitline voltage (VBLₛₜₑₚ). In another example, where N=2, for program verify loop 5 (PVFY 5), the control logic establishes an adjusted bitline voltage (VBL_{1+2N} or VBL₅) that is equal to the previous bitline voltage (VBL₃) plus the step bitline voltage (VBLₛₜₑₚ). In yet another example, where N=2, for program verify loop 7 (PVFY 7), the control logic establishes an adjusted bitline voltage (VBL_{1+3N}or VBL₇) that is equal to the previous bitline voltage (VBL₅) plus the step bitline voltage (VBLₛₜₑₚ).

At block 270, the control logic executes a next program verify loop associated with the programming level of the program operation with the adjusted bitline voltage applied to the subset of cells (i.e., the adjusted bitline voltage established in block 260).

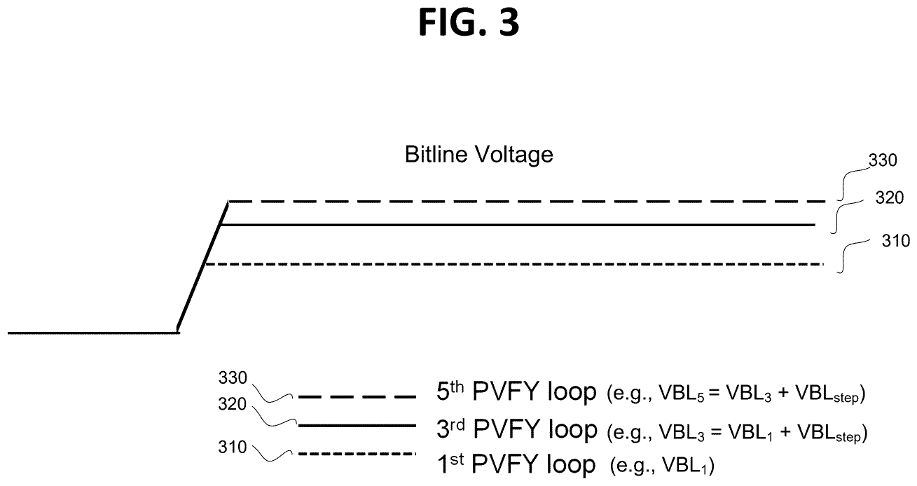

FIG. 3 is a diagram illustrating example program verify loop dependent bitline voltage levels applied to a subset of cells (i.e., the SSPC cells having a threshold voltage in the range between a pre-program verify voltage (PPV) and a program verify voltage (PV)) during program verify loops for each programming level during a program operation of a memory device, according to embodiments. As shown in the example of FIG. 3, during a first program verify loop (1^{st} PVFY loop), a first bitline voltage level 310 is applied to the subset of SSPC cells. In this example, during a third program verify loop (3^{rd} PVFY loop), a first adjusted bitline voltage level 320 is applied to the subset of SSPC cells. In this example, the first adjusted bitline voltage level 320 equals the first bitline voltage level 310 plus a step bitline voltage (VBLₛₜₑₚ). In this example, during a fifth program verify loop (5^{th} PVFY loop), a second adjusted bitline voltage level 330 is applied to the subset of SSPC cells. In this example, the second adjusted bitline voltage level 330 equals the first adjusted bitline voltage level 320 plus the step bitline voltage (VBLₛₜₑₚ). Although a fifth program verify loop is shown in FIG. 3, it is to be appreciated that any number of program verify loops may be employed during the programming of each programming level during the program operation, with the program verify loop dependent bitline voltage adjustments made in accordance with the process shown in FIG. 2.

With reference to FIG. 2, at block 280, the control logic determines if a last or final program verify loop has been executed. If not, the process 200 returns to block 230 to increase the program verify loop count and perform blocks 240-280 until reaching the final program verify loop. In an embodiment, during the last or final program verify loop for each programming level, a final bitline voltage level (VBL_{final}) is applied to the SSPC cells. In an embodiment, the final bitline voltage level (VBL_{final}) can be equal to a change in the program voltage (ΔVPGM) divided by a factor (e.g., two) (e.g., VBL_{final}=ΔVPGM/2; where the factor equals two). In an embodiment, the ΔVPGM represents the change or difference between the program voltages associated with the set of program pulses applied during the set of programming loops. Following the final program verify loop, the process 200 proceeds to block 290 and the control logic determines that the program operation is complete.

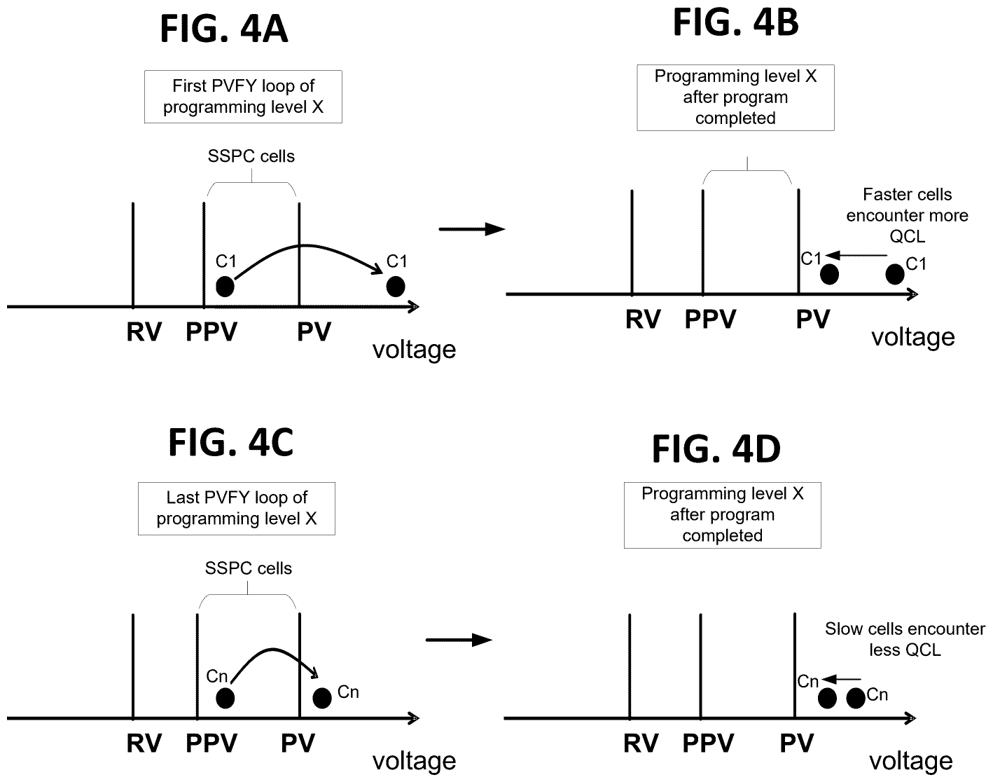

FIGS. 4A-4D illustrate an example of a SSPC program operation to program a set of cells to programming level X (e.g., where X is an integer such as 1, 2, 3, etc.) including program verify loop dependent adjustment of a bitline voltage applied to a subset of SSPC cells, according to embodiments of the present disclosure. As shown, during a first program verify loop associated with programming level X, a read voltage (RV), a pre-program verify voltage (PPV) and a program verify voltage (PV) are applied to determine if the cells are programmed to programming level X. As shown, a subset of cells (i.e., SSPC cells) in the range or region between the PPV and PV are identified, where the subset includes cell C1.

As shown in FIG. 4A, during the first program verify loop it is determined that a faster cell C1 (an example faster cell in the SSPC region) has a threshold voltage that is much higher than the PV voltage level. As a result, cell C1 is inhibited from a next program pulse (i.e., a second program pulse is not applied to cell C1). In an embodiment, during the first program verify loop for each programming level (e.g., programming level X), the SSPC cells are subjected to a first bitline voltage which results in fewer SSPC cells being slowed.

As shown in FIG. 4B, following completion of the program operation to program level X, due to the program verify loop dependent bitline adjustment process described in the present disclosure, the faster cells (e.g., cell C1) encounter more QCL to cause cell C1 to be placed closer to the PV voltage level, thereby resulting in an advantageously tighter distribution for programming level X.

As shown in FIG. 4C, during the final program verify loop it is determined that a cell Cn in the SSPC region has a threshold voltage that passes the PV voltage level that has been slowed such that the threshold voltage is closer to the PV level (as compared to cell C1). As shown in FIG. 4D, following completion of the programming of programming level X, due to the application of the program verify loop dependent bitline adjustment process described in the present disclosure, the slower cells (e.g., cell Cn) encounter less QCL such that the threshold voltage of Cn is closer to the PV voltage level, thereby resulting in an advantageously tighter distribution for programming level X.

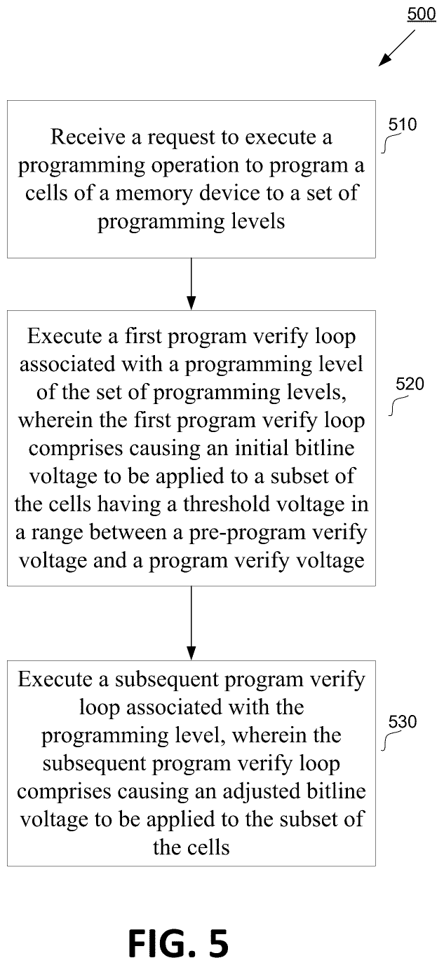

FIG. 5 is a flow diagram of an example method of an SSPC program operation including program verify loop dependent adjustment of a bitline voltage applied to a subset of SSPC cells, according to embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by program manager 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic (e.g., program manager 113) receives a request execute a programming operation to program cells of a memory device to a set of programming levels. In an embodiment, the program operation includes a series on programming loops including the application of a programming pulses (e.g., programming pulse 1, programming pulse 2, programming pulse 3 . . . programming pulse Y) having incrementally increasing program voltage levels (e.g., VPGM₁, VPGM₂, VPGM₃ . . . VPGM_{Y}).

At operation 520, the processing logic executes a first program verify loop associated with a programming level of the set of programming levels, wherein the first program verify loop comprises causing an initial bitline voltage to be applied to a subset of the cells having a threshold voltage in a range between a pre-program verify voltage (PPV) and a program verify voltage (PV). During each program verify loop, a read voltage (RV) is applied to read a threshold voltage associated with one or more cells to verify a programming state of those cells. In an embodiment, the identified subset of cells (i.e., SSPC cells) have a threshold voltage in a range or region between the PPV and the PV (i.e., the subset of faster cells that are easier to program and encounter a larger level of QCL).

At operation 530, the processing logic executes a subsequent program verify loop associated with the programming level, wherein the subsequent program verify loop comprises causing an adjusted bitline voltage to be applied to the subset of the cells. In an embodiment, the processing logic determines a count value associated with the subsequent program verify loop satisfies a condition. In an embodiment, the condition is satisfied if the count value equals one of a preset or determined values (e.g., the count value equals 3, 5, 7, etc.). In an embodiment, in response to determining that the condition is satisfied, the processing logic establishing the adjusted bitline voltage. In an embodiment, the adjusted bitline voltage equals the initial bitline voltage (VBL₁) increased by a step bitline voltage level (VBLₛₜₑₚ).

According to embodiments, for each program verify loop, the processing logic determines if the program verify loop count satisfies the condition (i.e., the current program verify loop count matches one of the conditional count values). Each time the condition is satisfied, the processing logic adjusts the bitline voltage applied to the subset of cells during the current program verify loop. In an embodiment, the processing logic establishes a new adjusted bitline voltage by increasing a current bitline voltage (i.e., a bitline voltage applied during a previous program verify loop) by the step bitline voltage level (VBLₛₜₑₚ).

In an embodiment, the processing logic identifies a last or final program verify loop and applies a final bitline voltage to the subset of SSPC cells. In an embodiment, during the last or final program verify loop for each programming level, a final bitline voltage level (VBL_{final}) is applied to the SSPC cells. In an embodiment, the final bitline voltage level (VBL_{final}) can be equal to a change in the program voltage (ΔVPGM) divided by a factor (e.g., two) (e.g., VBL_{final}=ΔVPGM/2; where the factor equals two).

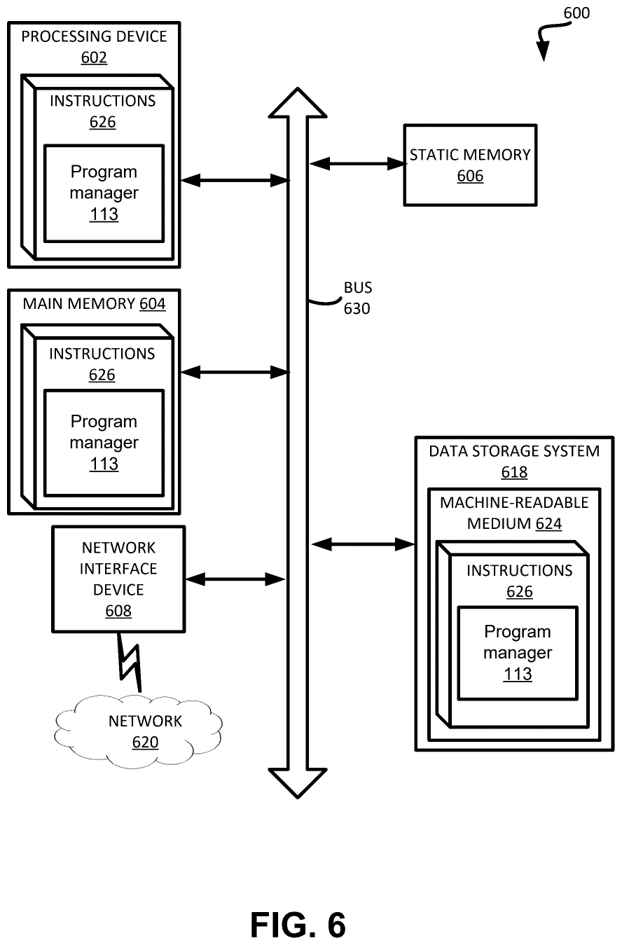

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the program manager 113 of FIG. 1A and FIG. 1B). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to the program manager 113 of FIG. 1A). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array; and
control logic, operatively coupled with the memory array, to perform operations comprising:
receiving a request to execute a programming operation to program cells of the memory array to a set of programming levels;
executing a first program verify loop associated with a programming level of the set of programming levels, wherein executing the first program verify loop comprises causing an initial bitline voltage to be applied to a subset of the cells having a threshold voltage in a range between a pre-program verify voltage and a program verify voltage; and
executing a subsequent program verify loop associated with the programming level, wherein executing the subsequent program verify loop comprises causing an adjusted bitline voltage to be applied to the subset of the cells.

2. The memory device of claim 1, the control logic is to perform operations further comprising:
determining a count value associated with the subsequent program verify loop satisfies a condition; and
in response to determining that the condition is satisfied, establishing the adjusted bitline voltage.

3. The memory device of claim 1, wherein the adjusted bitline voltage equals the initial bitline voltage increased by a step bitline voltage level.

4. The memory device of claim 1, the control logic is to perform operations further comprising:
determining a count value associated with a second subsequent program verify loop satisfies a condition; and
in response to determining that the condition is satisfied, establishing a second adjusted bitline voltage.

5. The memory device of claim 4, the control logic is to perform operations further comprising:
executing the second subsequent program verify loop associated with the programming level, wherein executing the second subsequent program verify loop comprises causing the second adjusted bitline voltage to be applied to the subset of the cells.

6. The memory device of claim 5, wherein the second adjusted bitline voltage equals the adjusted bitline voltage increased by a step bitline voltage level.

7. The memory device of claim 1, the control logic is to perform operations further comprising:
executing a final program verify loop associated with the programming level, wherein executing the final program verify loop comprises causing a final bitline voltage to be applied to the subset of the cells.

8. A method comprising:
receiving a request to execute a programming operation to program cells of a memory device to a set of programming levels;
executing a first program verify loop associated with a programming level of the set of programming levels, wherein executing the first program verify loop comprises causing an initial bitline voltage to be applied to a subset of the cells having a threshold voltage in a range between a pre-program verify voltage and a program verify voltage; and
executing a subsequent program verify loop associated with the programming level, wherein executing the subsequent program verify loop comprises causing an adjusted bitline voltage to be applied to the subset of the cells.

9. The method of claim 8, further comprising:
determining a count value associated with the subsequent program verify loop satisfies a condition; and
in response to determining that the condition is satisfied, establishing the adjusted bitline voltage.

10. The method of claim 8, wherein the adjusted bitline voltage equals the initial bitline voltage increased by a step bitline voltage level.

11. The method of claim 8, further comprising:
determining a count value associated with a second subsequent program verify loop satisfies a condition; and
in response to determining that the condition is satisfied, establishing a second adjusted bitline voltage.

12. The method of claim 11, further comprising:
executing the second subsequent program verify loop associated with the programming level, wherein executing the second subsequent program verify loop comprises causing the second adjusted bitline voltage to be applied to the subset of the cells.

13. The method of claim 12, wherein the second adjusted bitline voltage equals the adjusted bitline voltage increased by a step bitline voltage level.

14. The method of claim 8, further comprising:
executing a final program verify loop associated with the programming level, wherein executing the final program verify loop comprises causing a final bitline voltage to be applied to the subset of the cells.

15. A non-transitory computer-readable storage medium comprising instructions that, when executed by a processing device, cause the processing device to perform operations comprising:
receiving a request to execute a programming operation to program cells of a memory device to a set of programming levels;
executing a first program verify loop associated with a programming level of the set of programming levels, wherein executing the first program verify loop comprises causing an initial bitline voltage to be applied to a subset of the cells having a threshold voltage in a range between a pre-program verify voltage and a program verify voltage; and
executing a subsequent program verify loop associated with the programming level, wherein executing the subsequent program verify loop comprises causing an adjusted bitline voltage to be applied to the subset of the cells.

16. The non-transitory computer-readable storage medium of claim 15, the operations further comprising:
determining a count value associated with the subsequent program verify loop satisfies a condition; and
in response to determining that the condition is satisfied, establishing the adjusted bitline voltage.

17. The non-transitory computer-readable storage medium of claim 15, wherein the adjusted bitline voltage equals the initial bitline voltage increased by a step bitline voltage level.

18. The non-transitory computer-readable storage medium of claim 15, the operations further comprising:
determining a count value associated with a second subsequent program verify loop satisfies a condition; and
in response to determining that the condition is satisfied, establishing a second adjusted bitline voltage.

19. The non-transitory computer-readable storage medium of claim 18, further comprising:
executing the second subsequent program verify loop associated with the programming level, wherein the second subsequent program verify loop comprises causing the second adjusted bitline voltage to be applied to the subset of the cells, wherein the second adjusted bitline voltage equals the adjusted bitline voltage increased by a step bitline voltage level.

20. The non-transitory computer-readable storage medium of claim 15, further comprising:
executing a final program verify loop associated with the programming level, wherein the final program verify loop comprises applying a final bitline voltage to the subset of the cells.
